(19) United States
(12) Patent Application Publication
(10) Pub. No.: US 2015/0097274 A1
(43) Pub. Date: Apr. 9, 2015

(54) THROUGH-SILICON VIA STRUCTURE AND METHOD FOR IMPROVING BEOL DIELECTRIC PERFORMANCE

(71) Applicant: International Business Machines Corporation, Armonk, NY (US)

(72) Inventors: Christopher Collins, Wappingers Falls, NY (US); Mukta G. Farooq, Hopewell Junction, NY (US); Troy Lawrence Graves-Abe, Wappingers Falls, NY (US); Tze-Man Ko, Hopewell Junction, NY (US); William Francis Landers, Wappingers Falls, NY (US); Youbo Lin, Ridgefield, CT (US); Son Van Nguyen, Schenectady, NY (US); Jennifer Ann Oakley, Poughkeepsie, NY (US); Deepika Priyadarshini, Guilderland, NY (US)

(73) Assignee: International Business Machines Corporation, Armonk, NY (US)

(21) Appl. No.: 14/571,368

(22) Filed: Dec. 16, 2014

Related U.S. Application Data
(62) Division of application No. 14/023,980, filed on Sep. 11, 2013.

(51) Int. Cl. H01L 23/522; H01L 23/528; H01L 23/532

(52) U.S. Cl. CPC H01L 23/5226; H01L 23/5329; H01L 23/528
USPC 257/621

(57) ABSTRACT

An improved through-silicon via (TSV) is disclosed. A semiconductor substrate has a a back-end-of-line (BEOL) stack formed thereon. The BEOL stack and semiconductor substrate has a TSV cavity formed thereon. A conformal protective layer is disposed on the interior surface of the TSV cavity, along the BEOL stack and partway into the semiconductor substrate. The conformal protective layer serves to protect the dielectric layers within the BEOL stack during subsequent processing, improving the integrated circuit quality and product yield.

### CROSS REFERENCE TO RELATED APPLICATIONS

This application is a division of commonly-owned, copending U.S. patent application Ser. No. 14/023,980 entitled THROUGH-SILICON VIA STRUCTURE AND METHOD FOR IMPROVING BEOL DIELECTRIC PERFORMANCE and filed on Sep. 11, 2013.

### FIELD OF THE INVENTION

The present invention relates generally to semiconductor fabrication, and more particularly, to an improved through-silicon via.

### BACKGROUND OF THE INVENTION

There is an increasing demand for increased circuit density in integrated circuits (ICs) for a variety of applications. One technique for increased circuit density involves three-dimensional (3D) stacked chips, where die are stacked on top of one another to reduce the required space for an integrated circuit or to provide shorter interconnection paths between chips, such as between a logic chip and a memory chip A through-silicon via (TSV) technique is one of the 3D integration techniques that may be used to connect the various die that comprise the 3D stacked chip module. A “through hole” filled with a conductive material becomes wiring that functions as a conductive path after the filling, and is also referred to as a through-silicon via, or TSV. It is therefore desirable to have improvements in the fabrication of TSVs.

### SUMMARY OF THE INVENTION

In a first aspect, embodiments of the present invention provide a method of forming a through-silicon via (TSV) in a semiconductor structure comprising a semiconductor substrate with a back-end-of-line (BEOL) stack disposed thereon, the method comprising: forming a TSV cavity in the semiconductor substrate and back-end-of-line (BEOL) stack; performing a degas process on the semiconductor structure; depositing a conformal protective layer on the BEOL stack and along an interior surface of a substrate portion of the TSV cavity, wherein the conformal protective layer extends partway into the TSV cavity; depositing an insulating oxide layer in the TSV cavity; and filling the TSV cavity with a fill metal.

In a second aspect, embodiments of the present invention provide a method of forming a through-silicon via (TSV) in a semiconductor structure comprising a semiconductor substrate with a back-end-of-line (BEOL) stack disposed thereon, the method comprising: forming a TSV cavity in the semiconductor substrate and back-end-of-line (BEOL) stack; depositing a silicon nitride layer on the BEOL stack and along an interior surface of a substrate portion of the TSV cavity, wherein the silicon nitride layer extends from about 1 percent to about 10 percent into the TSV cavity; depositing an oxide layer in the TSV cavity; and filling the TSV cavity with a fill metal.

In a third aspect, embodiments of the present invention provide a semiconductor structure comprising: a silicon substrate; a back-end-of-line (BEOL) stack disposed on the silicon substrate, wherein the BEOL stack comprises a plurality of metal and dielectric layers; a through-silicon via (TSV) cavity formed in the BEOL stack and the silicon substrate; a conformal protective layer disposed on an interior surface of the BEOL stack and on an interior surface of the silicon substrate partway into a substrate portion of the TSV cavity; and a fill metal disposed in the TSV cavity, wherein the conformal protective layer is disposed between the BEOL stack and the fill metal.

### BRIEF DESCRIPTION OF THE DRAWINGS

The structure, operation, and advantages of the present invention will become further apparent upon consideration of the following description taken in conjunction with the accompanying figures (FIGs.). The figures are intended to be illustrative, not limiting. Certain elements in some of the figures may be omitted, or illustrated not-to-scale, for illustrative clarity. The cross-sectional views may be in the form of “slices”, or “near-sighted” cross-sectional views, omitting certain background lines which would otherwise be visible in a “true” cross-sectional view, for illustrative clarity.

Often, similar elements may be referred to by similar numbers in various figures (FIGs) of the drawing, in which case typically the last two significant digits may be the same, the most significant digit being the number of the drawing figure (FIG). Furthermore, for clarity, some reference numbers may be omitted in certain drawings.

FIG. 1 shows a semiconductor structure at a starting point for embodiments of the present invention.

FIG. 2 shows a semiconductor structure after a subsequent process step of forming a TSV cavity.

FIG. 3 shows a semiconductor structure after a subsequent process step of depositing a conformal protective layer.

FIG. 4 shows a semiconductor structure after a subsequent process step of depositing an oxide layer.

FIG. 5 shows a semiconductor structure after a subsequent process step of depositing additional liner layers.

FIG. 6 shows a semiconductor structure after a subsequent process step of depositing a fill metal in the TSV cavity.

FIG. 7 is a flowchart indicating process steps for embodiments of the present invention.

### DETAILED DESCRIPTION

An improved through-silicon via (TSV) and method of fabrication are disclosed. A back-end-of-line (BEOL) stack is formed on a semiconductor substrate. A TSV cavity is formed in the BEOL stack and semiconductor substrate. A conformal protective layer is disposed on the interior surface of the TSV cavity, along the BEOL stack and partway into the semiconductor substrate. The conformal protective layer serves to protect the dielectric layers within the BEOL stack during subsequent processing, improving the integrated circuit quality and product yield.

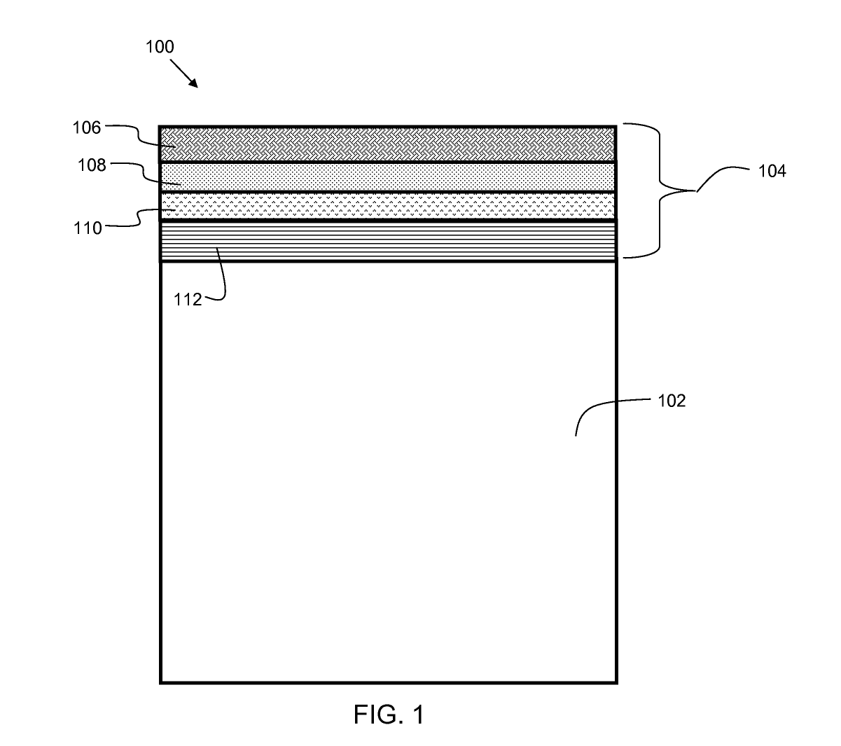

FIG. 1 shows a semiconductor structure 100 at a starting point for embodiments of the present invention. Semiconductor structure 100 comprises a bulk semiconductor substrate 102. In embodiments, substrate 102 comprises a silicon substrate, such as a silicon wafer. Disposed on substrate 102 is a back-end-of-line (BEOL) stack 104. BEOL stack 104 comprises a plurality of metallization layers and dielectric layers, indicated by layers 106, 108, 110, and 112. The depiction of BEOL stack 104 is intended merely to be illustrative. In practice, the BEOL stack 104 may comprise many more dielectric, metallization, and via layers. The integrity of the dielectric layers is important for fabricating reliable integrated circuits (ICs) and maintaining acceptable product yield.

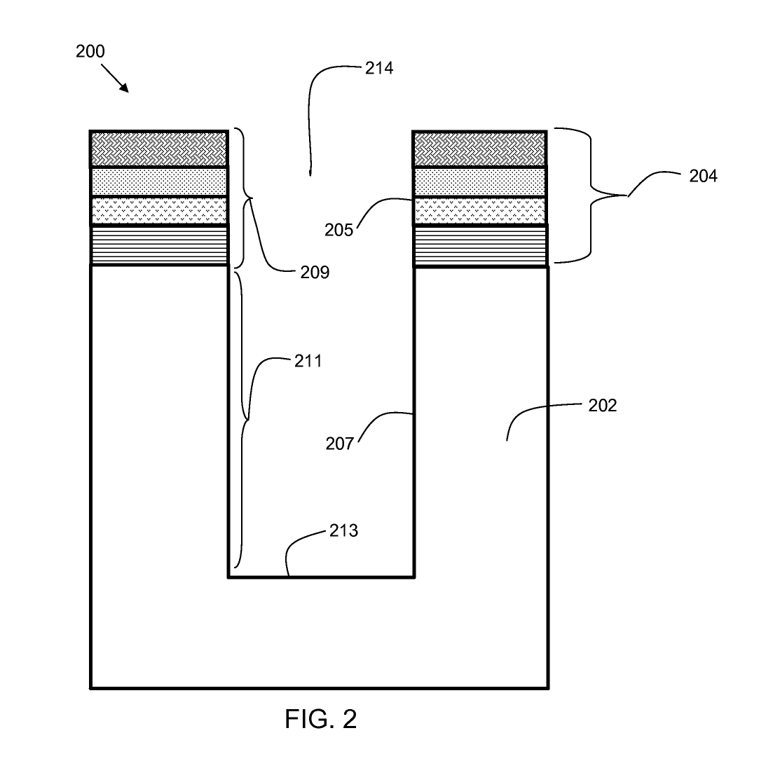

FIG. 2 shows a semiconductor structure 200 after a subsequent process step of forming a TSV cavity 214. As stated previously, similar elements may be referred to by similar numbers in various figures (FIGs) of the drawing, in which case typically the last two significant digits may be the same. For example, semiconductor substrate 202 of FIG. 2 is similar to semiconductor substrate 102 of FIG. 1. In embodiments TSV cavity 214 may be formed via industry-standard techniques which may include patterning and lithographic processes, followed by an etch process, such as a deep reactive ion etch (DRIE) process. The TSV cavity 214 comprises a BEOL portion 209 and a substrate portion 211. As a result, the TSV cavity 214 comprises a BEOL interior surface 205, and a substrate interior surface 207, and a base surface 213.

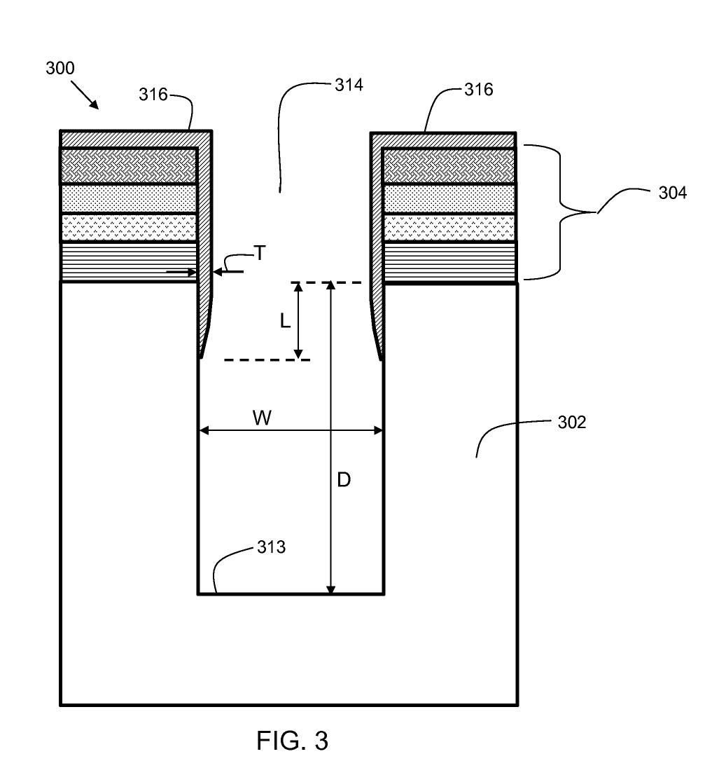

FIG. 3 shows a semiconductor structure 300 after a subsequent process step of depositing a conformal protective layer 316. In embodiments, a plasma activated conformal dielectric deposition may be used to deposit the conformal protective layer 316. Prior to depositing conformal protective layer 316, a degas process may be used to help remove moisture from the semiconductor structure 300. In embodiments, the degas process may be performed in the same deposition chamber used for depositing the conformal protective layer 316. In embodiments, the degas process may comprise subjecting the semiconductor structure 300 to a vacuum for a predetermined time interval. In some embodiments, the degas process may be performed at a vacuum level ranging from about 1 torr to about 10 torr. In some embodiments, the degas process may be performed for a duration ranging from about 8 minutes to about 12 minutes. In some embodiments, the degas process may be performed at a process temperature ranging from about 300 degrees Celsius to about 400 degrees Celsius. In some embodiments, the degas process may be performed at a vacuum level ranging from about 20 torr to about 40 torr. In some embodiments, the degas process may be performed for a duration ranging from about 9 minutes to about 11 minutes.

After the degas process is complete, the conformal protective layer 316 is deposited. In embodiments, the conformal protective layer 316 may comprise SiN (silicon nitride). In other embodiments, the conformal protective layer 316 may comprise SiCN (carbon-doped silicon nitride). In other embodiments, the conformal protective layer 316 may comprise a dielectric film of silicon oxide doped with nitrogen or carbon. The conformal protective layer 316 has a thickness T on the BEOL interior surface 205 (FIG. 2). In some embodiments, the conformal protective layer 316 has a thickness T ranging from about 10 nanometers to about 40 nanometers. In some embodiments, the conformal protective layer 316 has a thickness T ranging from about 15 nanometers to about 25 nanometers. The conformal protective layer 316 does not extend all the way to the base surface 313 of the TSV cavity 314. The TSV cavity 314 has a width W. In some embodiments, the width W may range from about 2 micrometers to about 6 micrometers. The TSV cavity 314 has a substrate portion depth D, which may range from about 50 micrometers to about 100 micrometers in some embodiments. The conformal protective layer deposition is adjusted such that the conformal protective layer 316 gradually gets thinner as it gets deeper into the TSV cavity 314, up to a depth of L, at which point the film of the conformal protective layer 316 is non-continuous or negligible. In embodiments, the depth L may range from about 1 percent to about 10 percent of the substrate portion depth D. Hence, in embodiments, the conformal protective layer 316 may extend from about 1 percent to about 10 percent into the substrate portion of the TSV cavity 314. This is important for downstream processing steps. With embodiments of the present invention, the termination of the conformal protective layer relatively early into the substrate portion of TSV cavity 314 simplifies the formation of insulating layers used to isolate the TSV from the substrate 302.

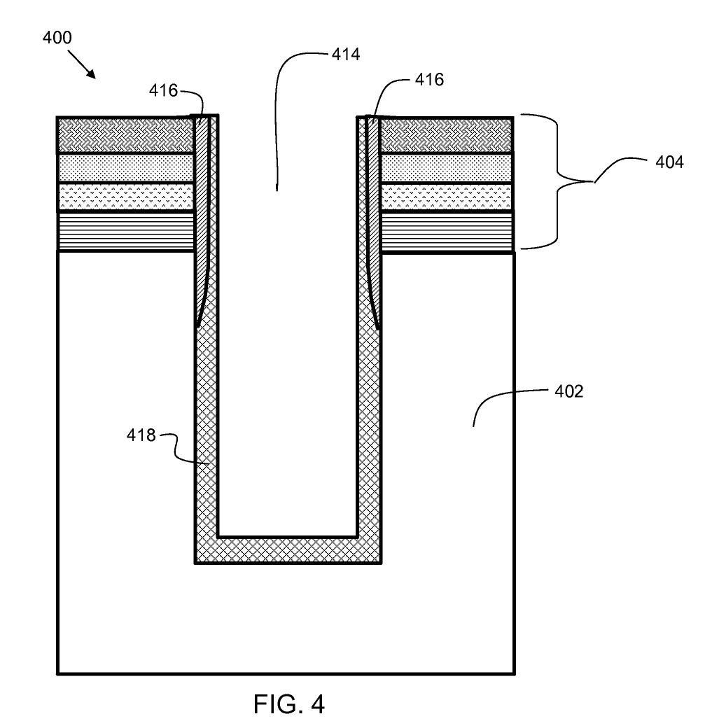

FIG. 4 shows a semiconductor structure 400 after a subsequent process step of depositing an insulating oxide layer 418 along the interior sidewalls and base of the TSV cavity 414. The oxide layer 418 serves to provide isolation between the TSV and the substrate 402. In embodiments, the oxide layer 418 may comprise a silicon oxide layer, and may be deposited via chemical vapor deposition.

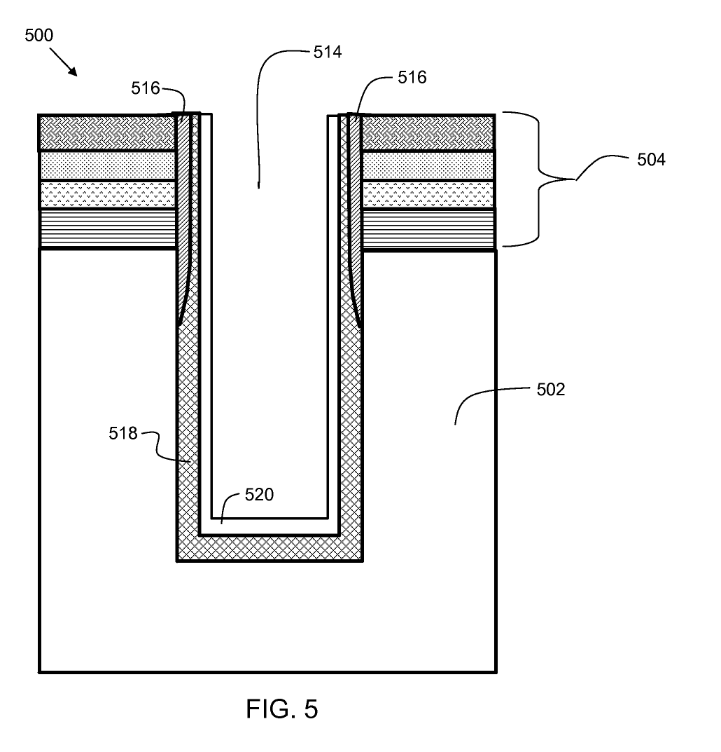

FIG. 5 shows a semiconductor structure 500 after a subsequent process step of depositing additional liner layer 520. Liner layer 520 may comprise multiple sublayers, including, but not limited to, diffusion barriers and adhesion films. Diffusion barriers may include tantalum nitride (TaN). Adhesion films may include, but are not limited to, tantalum, and additional films of materials such as copper or ruthenium may be deposited on top of the adhesion films. In embodiments, the various sublayers of liner layer 520 may be deposited via atomic layer deposition (ALD), or plasma vapor deposition (PVD), or other suitable technique.

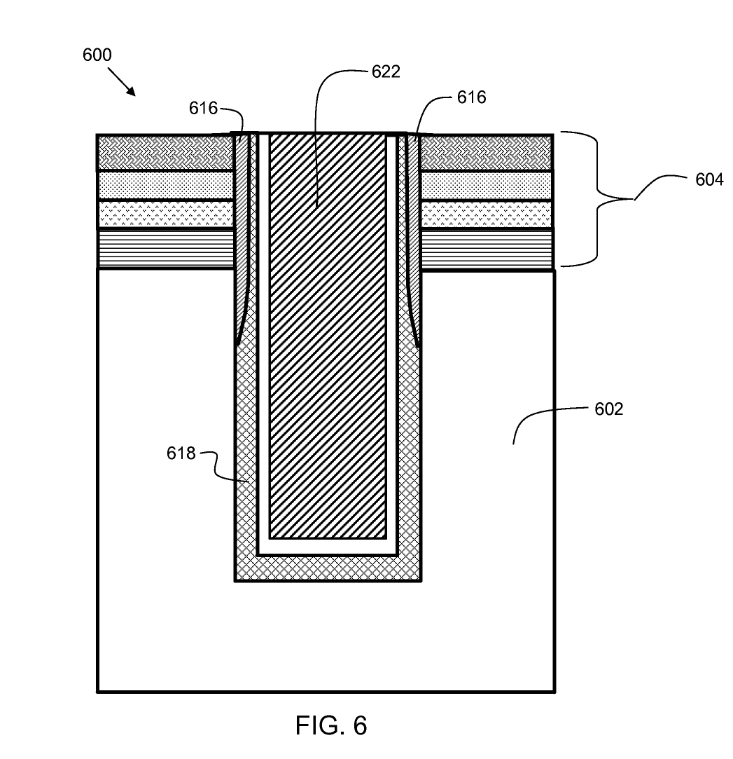

FIG. 6 shows a semiconductor structure 600 after a subsequent process step of depositing a fill metal 622 in the TSV cavity to form the TSV. In embodiments, fill metal 622 may include, but is not limited to, copper, tungsten, and aluminum. The fill metal 622 may be deposited via electro chemical deposition (ECD), chemical vapor deposition (CVD), or other suitable technique. Following the deposition of fill metal 622, a planarization process, such as a chemical mechanical polish (CMP) may be performed to planarize the fill metal 622 such that it is substantially flush with the top of the BEOL stack 604.

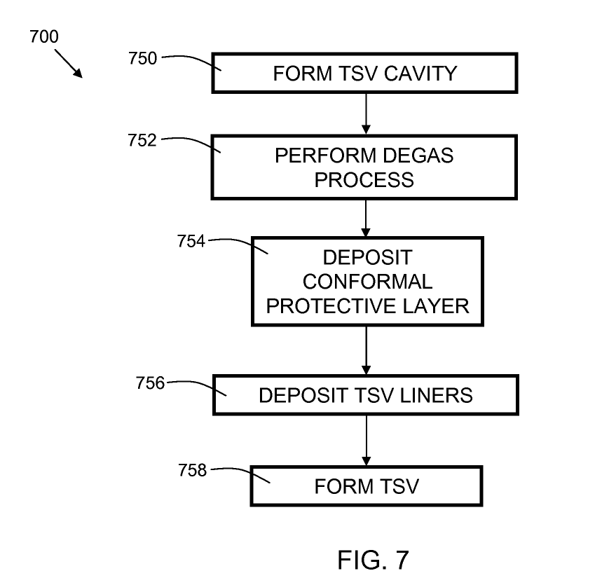

FIG. 7 is a flowchart 700 indicating process steps for embodiments of the present invention. In process step 750, a TSV cavity is formed in a semiconductor structure that comprises a semiconductor substrate with a BEOL stack disposed thereon. In process step 752, a degas process is performed. This helps remove moisture that could potentially cause problems with interlayer dielectric levels in subsequent processing steps. In process step 754, a conformal protective layer is deposited over the interior of the BEOL stack, and partway into the TSV cavity. In process step 756, TSV liners are deposited, including diffusion barriers and adhesion layers. In process step 758, the TSV is formed by depositing a fill metal such as copper, followed by planarization with a process such as a chemical mechanical polish process.

Although the invention has been shown and described with respect to a certain preferred embodiment or embodiments, certain equivalent alterations and modifications will occur to others skilled in the art upon the reading and understanding of this specification and the annexed drawings. In particular regard to the various functions performed by the above described components (assemblies, devices, circuits, etc.) the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary embodiments of the invention. In addition, while a particular feature of the invention may have been disclosed with respect to only one of several embodiments, such feature may be combined with one or more features of the other embodiments as may be desired and advantageous for any given or particular application.

What is claimed is:

1. A semiconductor structure comprising:
a silicon substrate;
a back-end-of-line (BEOL) stack disposed on the silicon substrate, wherein the BEOL stack comprises a plurality of metal and dielectric layers;
a through-silicon via (TSV) cavity formed in the BEOL stack and the silicon substrate;
a conformal protective layer disposed on an interior surface of the BEOL stack and on an interior surface of the silicon substrate partway into a substrate portion of the TSV cavity; and
a fill metal disposed in the TSV cavity, wherein the conformal protective layer is disposed between the BEOL stack and the fill metal.

2. The semiconductor structure of claim 1, wherein the conformal protective layer comprises silicon nitride.

3. The semiconductor structure of claim 1, wherein the conformal protective layer comprises SiCN.

4. The semiconductor structure of claim 1, wherein the conformal protective layer comprises a silicon oxide film doped with nitrogen.

5. The semiconductor structure of claim 1, wherein the conformal protective layer comprises a silicon oxide film doped with carbon.

6. The semiconductor structure of claim 1, wherein the conformal protective layer has a thickness ranging from about 15 nanometers to about 25 nanometers.

7. The semiconductor structure of claim 1, wherein the conformal protective layer extends from about 1 percent to about 10 percent into a substrate portion of the TSV cavity.

8. The semiconductor structure of claim 7, wherein the fill metal is comprised of copper.
